(19) United States
(12) Patent Application Publication
(10) Pub. No.: US 2018/0091123 A1
(43) Pub. Date: Mar. 29, 2018

(54) APPARATUS AND METHOD FOR GENERATING SINE WAVE

(71) Applicant: HYUNDAI MOTOR COMPANY, Seoul (KR)

(72) Inventors: Jae Hyeon PARK, Seoul (KR); Sang Hoon KWAK, Gwacheon-si (KR); Gun Soo KANG, Suwon-si (KR)

(73) Assignee: HYUNDAI MOTOR COMPANY, Seoul (KR)

(21) Appl. No.: 15/374,086

(22) Filed: Dec. 9, 2016

(30) Foreign Application Priority Data
Sep. 26, 2016 (KR) 10-2016-0123039

(51) Int. Cl. H03K 3/80

(52) U.S. Cl. CPC H03K 3/80

(57) ABSTRACT

Disclosed is an apparatus for generating high-quality sine waves through a simple circuit structure. The apparatus comprises a square wave generator for generating a plurality of square waves different in frequency from one to another; a combined circuit for combining the plurality of square waves into a synthetic wave; and a filter circuit for filtering the synthetic wave through a low-pass filter. Also, a method for generating high-quality sine waves is provided.

### CROSS REFERENCE TO RELATED APPLICATION

The present application claims priority to Korean Patent Application No. 10-2016-0123039, filed Sep. 26, 2016, the entire contents of which is incorporated herein for all purposes by this reference.

### BACKGROUND

### Field

The present disclosure relates to an apparatus and a method for generating a sine wave. More particularly, the present disclosure relates to an apparatus and a method for generating a high-quality sine wave, using a simple circuit structure.

### Description of the Related Art

Generally, control circuits need high-quality sine waves for various purposes. For example, an excitation signal for driving a sensor is input to a resolver circuit for detecting position information of a driving motor in an eco-friendly car. The accuracy of the position information of the motor depends on the stability and quality of a sine wave input into the resolver circuit, and accurate position information is indispensable for enhancing motor control.

However, a digital circuit can generate only square waves consisting fundamentally of 0 (zero) and 1, but cannot directly generate sine waves. Hence, digital circuits are structured to generate sine waves from square waves.

The disclosure of this section is to provide background of the invention. Applicant notes that this section may contain information available before this application. However, by providing this section, Applicant does not admit that any information contained in this section constitutes prior art.

### SUMMARY

An aspect of the present disclosure is to provide an apparatus and a method for generating high-quality sine waves through a simple circuit structure.

A square wave generated in a digital circuit, such as a micro-controller, is subjected to pass through multiple low-pass filters for generating a sine wave. Multiple stages of low-pass filters complicate circuit architectures and may results in low efficiency in removing second and third harmonics, which have great influences on the distortion of signals, with the consequent quality degradation of produced sine waves.

In accordance with an aspect thereof, the present disclosure provides an apparatus for generating a sine wave, comprising: a square wave generator for generating a plurality of square waves different in frequency from one to another; a combined circuit for combining the plurality of square waves into a synthetic wave; and a filter circuit for filtering the synthetic wave through a low-pass filter.

In one embodiment, the plural square waves may comprise a first square wave having a frequency equivalent to that of the sine wave of target, and at least one second square wave having a higher frequency of odd numbers than the frequency of the first square wave.

In another embodiment, the first square wave and the second square wave may be in anti-phase.

In another embodiment, the combined circuit may comprise a plurality of input terminals for respectively receiving the plurality of square waves, an output terminal connected to an input terminal, of a filter circuit, and a plurality of respective resistances between the plurality of input terminals and the output terminal.

In another embodiment, the combined circuit may reduce amplitude of the second square wave by a frequency ratio of the second square waves to the first square wave before the second square wave is combined with the first square wave.

In another embodiment, the filter circuit may comprise: an input terminal for receiving the synthetic waver, a first resistance connected to the input terminal, a first capacitor communicating between the first resistance and a ground, an operational amplifier having an inverting input terminal and a non-inverting input terminal communicating with the first resistance, a second resistance and a second capacitor, connected in parallel with each other between the inverting input terminal and non-inverting output terminal of the operational amplifier, a third resistance connecting between the inverting input terminal of the operational amplifier and a ground, and a capacitor connecting between an output terminal of the operational amplifier and the input terminal of the filter circuit, the output terminal of the operation amplifier outputting the sine wave.

In another embodiment, the apparatus may further comprise an offset circuit for applying a direct-current offset voltage to the sine wave output from the filter circuit.

In another embodiment, the offset circuit may comprise: a plurality of voltage-dividing resistances connecting between a source voltage and a ground, and an output terminal for outputting a sine wave to which an offset voltage is applied at a connecting node between the plural voltage-dividing resistances.

In accordance with another aspect thereof, the present disclosure provides a method for generating a sine wave, comprising: generating a first square wave having a frequency equivalent to that of the sine wave of target, and at least one second square wave having a higher frequency of odd numbers than the frequency of the first square wave; combining the first square wave and the second square wave into one synthetic wave; and filtering the synthetic wave through a low-pass filter.

In one embodiment, the first square wave and the second square wave may be in anti-phase.

In another embodiment, the method may further comprise applying an offset voltage to the sine wave generated in the combining step.

In another embodiment, the combining step may further comprise reducing amplitude of the second square wave by a frequency ratio of the second square waves to the first square wave before the second square wave is combined with the first square wave.

According to the apparatus and apparatus for generating a sine wave, as described hitherto, a square wave corresponding to a harmonic component is produced, in advance, combined with a square wave having a fundamental frequency, and filtered to easily remove the harmonics without using multiple filters. Because advantage is taken of the function of a square wave generator such as a microcontroller in producing multiple square waves, the overall circuit can be simplified with the concomitant production of high-quality sine wave signals free of harmonics.

Accordingly, the apparatus and the method for generating a sine wave in accordance with the present disclosure are economically advantageous because of the simple hardware composition thereof, In addition, the apparatus and the method provide harmonic-controlled, high-quality sine waves that can make a contribution to improving the functions of various controllers.

### BRIEF DESCRIPTION OF THE DRAWINGS

The above and other features and other advantages of the present invention will be more clearly understood from the following detailed description when taken in conjunction with the accompanying drawings, in which:

FIG. 1 is a block diagram explaining an apparatus for generating a sine wave in accordance with an embodiment of the present disclosure;

FIG. 2 is a circuit diagram depicting in greater detail an apparatus for generating a sine wave in accordance with an embodiment of the present disclosure.

FIG. 3 is a block diagram of an apparatus including two low-pass filters for generating a sine wave; and

FIGS. 4 and 5 are spectra of sine wave signals generated by the apparatus of in FIG. 3 and an apparatus for generating a sine wave according to embodiments of the present invention, respectively.

### DETAILED DESCRIPTION

Below, a description will be given of an apparatus and a method for generating a sine wave according to some embodiments thereof with reference to the accompanying drawings.

One aspect of the present invention provides a system for producing sine wave signals of a target frequency using two or more square wave signals having different frequencies. Square wave signals from the square wave generator 100 are fed directly or indirectly to a low-pass filter 20 for producing the target frequency sign wave signals.

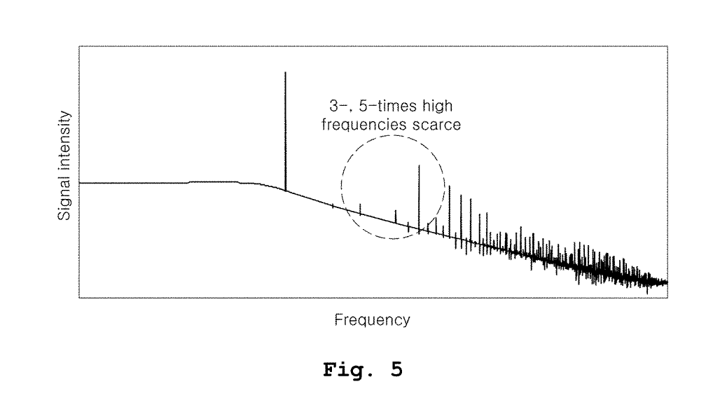

When square wave signals of the target frequency are fed to the low-pass filter 20, the resulting sine wave signals comprises undesirable high order harmonic components as illustrated in FIG. 4. In embodiments, to reduce such harmonic sine wave components in the resulting signals, at least one square wave signals having a different frequency from the target frequency are additionally fed to the low-pass filter.

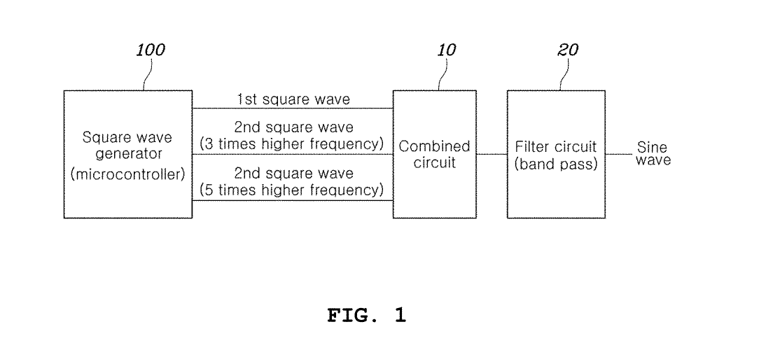

In embodiments, the square wave generator 100 is capable of generating two or more square wave signals in different frequencies simultaneously. In embodiments, the square wave generator generates a target frequency square wave signals (1^{st} square wave in FIG. 1) and an additional square wave signals (2^{nd} square wave in FIG. 1) having the same frequency as the undesirable high order (odd order of 3 or 5) harmonic components. In embodiments, the target frequency square wave signals and the additional square wave signals are in antiphase (180-degree phase difference).

In embodiments, a circuit 10 combines multiple square wave signals from the square wave generator 100 into a single input signal of the low-pass filter 20. In the input signal of the low-pass filter 20, the target frequency square wave component and the additional square wave component having the same frequency as the undesirable high order harmonic component are in antiphase such that high order harmonic components resulting from the target frequency square wave components are canceled with low-pass filtered additional square wave component.

In embodiment, the target frequency square wave signals (1^{st} square wave in FIG. 1) and, the additional square wave signals from the square wave generator are the same. When the circuit 10 produces the input signals, the circuit 10 adjusts at least one of the amplitudes of square wave signal components such that, in the input signals, ratio between amplitudes of the target frequency (order of 1) component and the harmonic frequency (order of 3 or 5) component are inverse proportion of the ratio between orders of the frequencies.

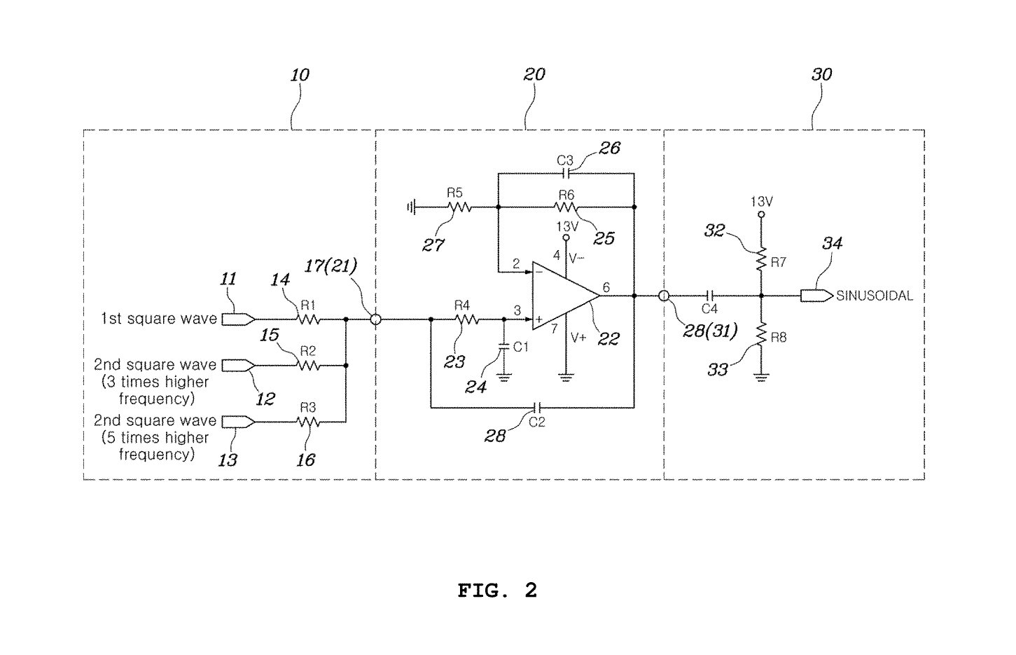

FIG. 1 is a block diagram explaining an apparatus for generating a sine wave in accordance with, an embodiment of the present disclosure. FIG. 2 is a circuit diagram depicting in greater detail an apparatus for generating a sine wave in accordance with an embodiment of the present disclosure.

With reference to FIG. 1, the apparatus for generating a sine wave in accordance with an embodiment of the present disclosure may comprise a square wave generator 100, an integrated circuit 10, and a filter circuit 20. In addition, the apparatus may further comprise an offset circuit 30.

The square wave generator 100 can generate multiple square waves that are different in frequency from one to another. For example, the square wave generator 100 may be a microcontroller that can generate square waves in which ‘0 (LOW)’ and ‘1 (HIGH)’ are repetitively alternated at identical time intervals. Here, ‘0’ and ‘1’ do not mean physical values, but indicate states of binary signals that can be output in a digital circuit. The respective voltage levels that ‘0’ and ‘1’ can output are pertinently determined as needed. On the whole, the LOW and HIGH signals output from a digital circuit can be the source voltage of the digital circuit. For a microcontroller using a source voltage of +5 V, by way of example, ‘0 (LOW)’ may be 0 V, which corresponds to a ground while ‘1 (HIGH)’ may be 5 V that accounts for the source voltage.

In some embodiments of the present disclosure, the square wave generator 100 may generate a first square wave having a predetermined frequency and at least one second square wave having a higher frequency of odd numbers (orders).

Here, the first square wave has a frequency identical to that of the final sine wave to be generated by the apparatus in accordance with some embodiments of the present disclosure. In addition, the second square wave may have a frequency corresponding to a harmonic component that may occur when sine waves are generated in a filtering manner. On the whole, multiple-order harmonics may occur when sine waves are generated in a filtering manner. The harmonics appear as odd-integer frequencies of a fundamental frequency, that is, a sine wave frequency to be generated. In consideration of the fact that harmonics with frequencies three- or five-times the fundamental frequency are most abundant, a description will be given of the case where the frequency of the second square wave is three or five times that of the first square wave.

The second square wave generated in the square wave generator 100 is combined with the first square wave to counterbalance harmonic components present in the finally generated sine wave. Considering that the generated harmonic components have the same phase as the generated sine wave, the square wave generator 100 operates in such a manner that the first square wave and the second square wave are in anti-phase (180-degree phase difference). That is, when the first square wave starts at a section of HIGH state as generated by the square wave generator 100, the second square wave is output from a section of LOW state.

The combined circuit 10 combines the first square wave and the second square wave, both generated in, the square wave generator 100, into a synthetic wave. For example, the combined circuit 10 may comprise a plurality of input terminals 11 to 13 that receive a plurality of square waves generated by the square wave generator 100, respectively, an output terminal 17 connected to an input terminal of a filter circuit 20, and a plurality of respective resistances 14 to 16 between the plurality of input terminals 11 to 13 and the output terminal 17.

In the combined circuit 10, the second square wave is adapted to counterbalance a harmonic component that may occur in a subsequent filtering procedure. Considering fact that the amplitude of the harmonic component is smaller than that of the sine wave having a main frequency, values of the multiple resistances 14 to 16 may be determined. On the basis of the fact that the amplitude of a harmonic component generated through one filter circuit can be in inverse proportion to frequency, the resistances 14 to 16 can be provided to reduce the amplitudes of the second square waves by the frequency ratios of the second square waves to the first square wave. For example, when two second square waves have three and five times the main frequency, respectively, the resistances 14 to 16 of the combined circuit 10 may be designed to reduce the amplitude of the two second square waves into ⅓ and ⅕ of the main amplitude, respectively. In this regard, the resistances 14 to 16 may be provided with a resistance ratio of 1:3:5. Of course, this resistance design is made under the assumption that the first square wave and the second square wave, generated in the square wave generator, have the same amplitude.

After their amplitudes are controlled by respective resistances 14 to 16, the square waves input into the input terminals 11 to 13 are combined in one node and then output from the output terminal 17.

The filter circuit 20 functions to form a square wave by passing the synthetic wave produced in the combined circuit 10 through a low-pass filter. According to some embodiments of the present disclosure, the filter circuit 20 may be embodied as various filter circuit structures known in the art, The filter circuit 20 depicted in FIG. 2 is one example of a non-inverting second-order low-pass filter.

In greater detail, the filter circuit 20 may comprise an input terminal 21 for receiving the synthetic waver, a resistance 23 connected to the input terminal 21, a capacitor 24 communicating between the resistance 23 and a ground, an operational amplifier 22 having an inverting input terminal, and a non-inverting input terminal communicating with a connecting node of both the resistance and the capacitor 24, a resistance 25 and a capacitor 26, connected in parallel with each other between the inverting input terminal and non-inverting output terminal of the operational amplifier 22, a resistance 27 connecting between the inverting input terminal of the operational amplifier and a ground, and a capacitor 28 connecting between an output terminal of the operational amplifier 22 and the input terminal 21.

The filter circuit 20 depicted in FIG. 2 is an example of a third-order low-pass filter in which three poles and three zeroes are formed by the resistance 23 and the capacitors 24 and 28, all connected to the non-inverting input terminal of the operational amplifier 20, and the resistance 25 and the capacitor 26, connected in parallel with each other between the inverting input terminal and the output terminal of the operational amplifier 22. The output terminal of the operational amplifier 20 also acts as the output terminal 28 of the filter circuit 20. Through the output terminal 28, the sine wave generated by low-pass filtering is output.

The offset circuit 30 is adapted to balance the overall level, of the sine wave by applying a DC offset voltage to the sine wave output from the filter circuit 20.

In greater detail, the offset circuit 30 may comprise a plurality of voltage-dividing resistances 32 and 33 connecting between a source voltage and a ground, and an output terminal 34 for outputting a sine wave to which an offset voltage is applied at a connecting node between the plural voltage-dividing resistances 32 and 33. An input terminal of the offset circuit 30 is connected to the output terminal of the filter circuit 20. In the offset circuit 30, the sine wave input into the input terminal is applied to the connecting node between the voltage-dividing resistances 32 and 33 in which the source voltage is divided, whereby the sine wave output from the filter circuit 20 experiences a level change by the magnitude of the direct voltage applied to the connecting node and is output from the output terminal 34 of the offset circuit 30.

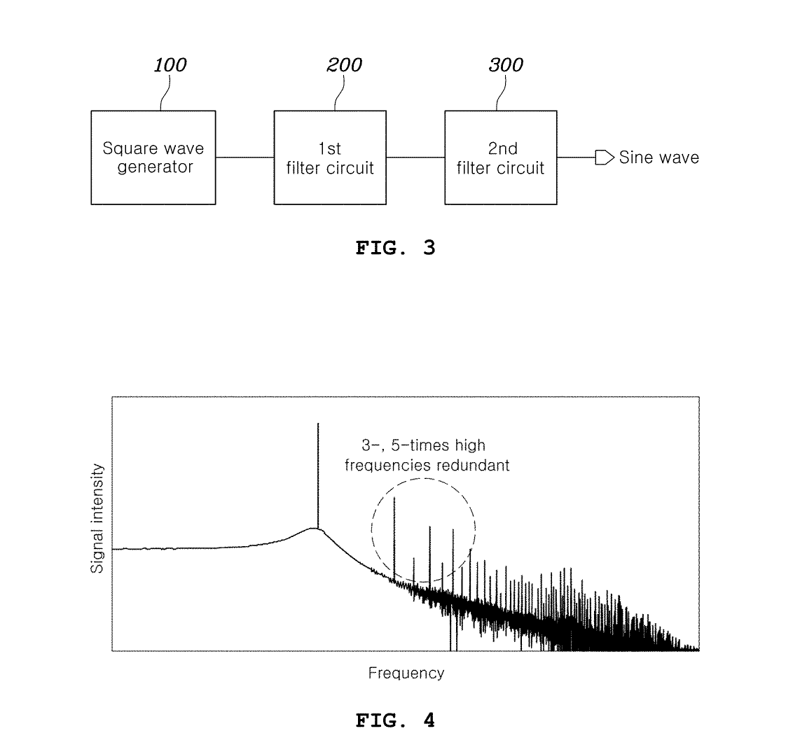

FIG. 3 is a block diagram of an apparatus for generating a sine wave. FIGS. 4 and 5 are spectra of sine wave signals generated by the apparatus of FIG. 3 for generating a sine wave and an apparatus for generating a sine wave according to embodiments of the present invention, respectively.

As shown in FIG. 3, the apparatus for generating a sine wave comprises a square wave generator 100 for generating a single frequency square wave having the same frequency as a target sine wave, a first filter circuit 200 for filtering the square wave generated by the square wave generator through a low-pass filter, and a second filter circuit 300 for filtering the signal filtered by the first filter circuit 200 through a low-pass filter.

As stated above, the apparatus of FIG. 3 for generating a sine wave employs multiple filter circuits so that its hardware is expensive. In addition, its performance for restraining harmonic components is limited. This can be well understood from the output spectrum of the apparatus as shown in FIG. 4.

Referring to FIG. 4, abundant harmonics with frequencies three and five times the fundamental frequency are generated by the apparatus of FIG. 3 in spite of multiple filtering stages.

Turning to FIG. 5, the apparatus for generating a sine wave in accordance with an embodiment of the present disclosure greatly reduces harmonics components having frequencies three- and five-times the fundamental frequency, thus generating a high-quality sine wave.

In the apparatus for generating a sine wave in accordance with some embodiments of the present disclosure, as described hitherto, square wave corresponding to a harmonic component is produced in advance, combined with a square wave having a fundamental frequency, and filtered to easily remove the harmonics without using multiple filters. Because advantage is taken of the function of a square wave generator such as a microcontroller in producing multiple square waves, the overall circuit can be simplified with the concomitant production of high-quality sine wave signals free of harmonics.

Accordingly, the apparatus for generating a sine wave in accordance with the present disclosure is economically advantageous compared to apparatuses using a single frequency square wave because it has a simple hardware composition with reduced numbers of low pass filters. In addition, the apparatus provides harmonic-controlled, high-quality sine waves that can make a contribution, to improving the functions of various controllers.

Although the present invention was described with reference to specific embodiments shown in the drawings, it is apparent to those skilled in the art that embodiments of the present invention may be changed and modified in various ways.

What is claimed is:

1. An apparatus for generating a sine wave, comprising:
a square wave generator for generating a plurality of square waves different in frequency from one to another;
a combined circuit for combining the plurality of square waves into a synthetic wave; and
a filter circuit for filtering the synthetic wave through a low-pass filter.

2. The apparatus of claim 1, wherein the plural square waves comprise a first square wave having a frequency equivalent to that of the sine wave of target, and at least one second square wave having a higher frequency of odd numbers than the frequency of the first square wave.

3. The apparatus of claim 2, wherein the first square wave and the second square wave are in anti-phase.

4. The apparatus of claim 1, wherein the combined circuit comprises a plurality of input terminals for respectively receiving the plurality of square waves, an output terminal connected to an input terminal of a filter circuit, and a plurality of respective resistances between the plurality of input terminals and the output terminal.

5. The apparatus of claim 2, wherein the combined circuit reduces amplitude of the second square wave by a frequency ratio of the second square waves to the first square wave before the second square wave is combined with the first square wave.

6. The apparatus of claim 1, wherein the filter circuit comprises:
an input terminal for receiving the synthetic waver,
a first resistance connected to the input terminal,
a first capacitor communicating between the first resistance and a ground,
an operational amplifier having an inverting input terminal and a non-inverting input terminal communicating with the first resistance,
a second resistance and a second capacitor, connected in parallel with each other between the inverting input terminal and non-inverting output terminal of the operational amplifier,
a third resistance connecting between the inverting input terminal of the operational amplifier and a ground, and
a capacitor connecting between an output terminal of the operational amplifier and the input terminal of the filter circuit, the output terminal of the operation amplifier outputting the sine wave

7. The apparatus of claim 1, further comprising an offset circuit for applying a direct-current offset voltage to the sine wave output from the filter circuit.

8. The apparatus of claim 8, wherein the offset circuit comprises:
a plurality of voltage-dividing resistances connecting between a source voltage and a ground, and
an output terminal for outputting a sine wave to which an offset voltage is applied at a connecting node between the plural voltage-dividing resistances.

9. A method for generating a sine wave, comprising:
generating a first square wave having a frequency equivalent to that of the sine wave of target, and at least one second square wave having a higher frequency of odd numbers than the frequency of the first square wave;
combining the first square wave and the second square wave into one synthetic wave; and
filtering the synthetic wave through a low-pass filter.

10. The method of claim 9, wherein the first square wave and the second square wave are in anti-phase.

11. The method of claim 9, further comprising applying an offset voltage to the sine wave generated in the combining step.

12. The method of claim 9, wherein the combining step further comprises reducing amplitude of the second square wave by a frequency ratio of the second square waves to the first square wave before the second square wave is combined with the first square wave.
